(19) United States
(12) Patent Application Publication
(10) Pub. No.: US 2026/0220193 A1
(43) Pub. Date: Jul. 30, 2026

(54) Music Playing System Based on a Location and a Solar Term, and its Music Recommendation Method and Player

(71) Applicant: Qiuli Zhang, Yuxi City, Yunnan Province (CN)

(72) Inventor: Qiuli Zhang, Yuxi City, Yunnan Province (CN)

(21) Appl. No.: 19/145,946

(22) PCT Filed: Feb. 20, 2023
(86) PCT No.: PCT/CN2023/077206

§ 371 Date: Jul. 7, 2025

(30) Foreign Application Priority Data
Jan. 5, 2023 (CN) 202310011199.7
Feb. 7, 2023 (CN) 202310101102.1

(51) Int. Cl. G06F 16/635; G06F 16/638; G06F 16/65; G06F 16/687

(52) U.S. Cl. CPC G06F 16/636; G06F 16/639; G06F 16/65; G06F 16/687

(57) ABSTRACT

Disclose is a position and solar term-based music player. A birth solar term of a user is obtained by obtaining the date of birthday of the user. A conditioning frequency of the user is obtained according to the birth solar term of the user. According to the condition frequency of the user, the position and solar term-based music player obtains music with the conditioning frequency for playback.

### BACKGROUND OF THE PRESENT INVENTION

### Field of Invention

The present invention relates to a music playing system and a player, and more particularly to a music playing system and its player, in particular to a music playing system and its player based on a location and a solar term.

### Description of Related Arts

Food is the main way people get energy. By eating, food is converted into the energy people need to grow up. However, some situations are not suitable to supplement energy by eating, and some energy cannot be supplemented by eating. Replenishing energy through a music is an alternative way to replenish energy. Sound travels in the form of sound waves, and the sound is thought to be a form of energy transmission. The music is a form of expression of sound. Therefore, through music is also a form of energy transmission. For example, a doctor of a surgery who play music to relieve stress during the surgery have been shown to be effective in practice. Specifically, in the process of the surgery, the doctor needs to supplement the consumed energy due to relieve stress, the doctor supplements the consumed energy by choosing to play music. Moreover, a classical music is one of the most popular options for the doctors. In the classical music, the classical masters such as Mozart, Beethoven, Bach and other masters choose to use 432 Hertz for their creation. In other words, the music transmitted at a selected frequency has a specific effect on a selected person. For example, during the surgery, playing the classical music composed at 432 Hertz can relieve stress for the doctors.

Current streaming media comprises QQ Music, NetEase Cloud Music, Apple Music, Amazon Music, Ku Gou, Huawei Music, Tik Tok and so on. This streaming media software offer music libraries. Users can choose their favorite music to play in the music library according to the music type, album, and musician. However, in the current streaming media music, there is no way to select music based on music frequency. The current music streaming media have the membership functions, and the members'birthdays are only recorded as the basic information of the members. The current streaming media apps only offer the members a discounted renewal plan on their birthday. In other words, the current streaming software's understanding of the user's birthday is limited to the user's birth date. Because of the incomplete understanding of the information contained in the user's birthday, the current streaming media software cannot implement the music recommendation based on the user's birthday. It is worth mentioning that the current streaming media has no concept of solar terms and lacks understanding of the solar terms. Therefore, it is not possible to recommend music according to the solar terms.

The current streaming media music software has a playlist function, but these playlists can only be added actively by the users. The specific operation is that the user first adds the playlist, and then adds the corresponding song to the playlist. In other words, the users simply create the playlists based on their own preferences. The current market of the streaming media music software only provides the users with the ability to create their own playlists.

With the popularity of we-media, the threshold to enter a music industry has been lowered. A music producer can display the music produced by the music producer through the we-media. However, within the current music showed by the streaming media music, there is no music showed for the place where the user is in.

To search for the local musicians and/or the local music, the name of the music creator or the name of the music is needed to be known in order to get search results, and the music created by the local music producer cannot be required according to the current location of the user.

### SUMMARY OF THE PRESENT INVENTION

The invention is advantageous in that it provides a music playing system and its player based on a location and a solar term, wherein the music playing system and its player based on the location and the solar term can select a music to play according to a current location.

Another advantage of the present invention is to provide a music playing system and its player based on a location and a solar term, wherein the music playing system and its player based on the location and the solar term generate a playlist according to the current location.

Another advantage of the present invention is to provide a music playing system and its player based on a location and a solar term, wherein the music playing system and its player based on the location and the solar term recommend the music according to a music frequency.

Another advantage of the present invention is to provide a music playing system and its player based on a location and a solar term, wherein the music playing system and its player based on the location and the solar term generate the playlist according to the music frequency.

Another advantage of the present invention is to provide a music playing system and its player based on a location and a solar term, wherein the music playing system and its player based on the location and the solar term recommend the music according to a birth information.

Another advantage of the present invention is to provide a music playing system and its player based on a location and a solar term, wherein the music playing system and its player based on the location and the solar term generate the playlist according to the birth information.

Another advantage of the present invention is to provide a music playing system and its player based on a location and a solar term, wherein the music playing system and its player based on the location and the solar term recommend the music according to the solar term.

Another advantage of the present invention is to provide a music playing system and its player based on a location and a solar term, wherein the music playing system and its player based on the location and the solar term generate the playlist according to the solar term.

Another advantage of the present invention is to provide a music playing system and its player based on a location and a solar term, wherein the music playing system and its player based on the location and the solar term interpret the birth date to further obtain the information contained in the birthday.

Another advantage of the present invention is to provide a music playing system and its player based on a location and a solar term, wherein the music playing system and its player based on the location and the solar term further obtain the information contained in the birthday according to the birth place.

Another advantage of the present invention is to provide a music playing system and its player based on a location and a solar term, wherein the music playing system and its player based on the location and the solar term obtain the music frequency suitable for the current user according to the birth date.

Another advantage of the present invention is to provide a music playing system and its player based on a location and a solar term, wherein the music playing system and its player based on the location and the solar term select the music suitable for the current user according to the music frequency suitable for the current user.

Another advantage of the present invention is to provide a music playing system and its player based on a location and a solar term, wherein the music playing system and its player based on the location and the solar term select multiple corresponding pieces of music to form the playlist according to the music frequency suitable for the current music.

Another advantage of the present invention is to provide a music playing system and its player based on a location and a solar term, wherein the music playing system and its player based on the location and the solar term generate the music according to the music frequency suitable for the current user.

Another advantage of the present invention is to provide a music playing system and its player based on a location and a solar term, wherein the music playing system and its player based on the location and the solar term update the played music according to the change of the current location.

Another advantage of the present invention is to provide a music playing system and its player based on a location and a solar term, wherein the music playing system and its player based on the location and the solar term play the playlist according to the change of the current location.

Another advantage of the present invention is to provide a music playing system and its player based on a location and a solar term, wherein the music playing system and its player based on the location and the solar term generate the music according to the frequency corresponding to the instruments.

Another advantage of the present invention is to provide a music playing system and its player based on a location and a solar term, wherein the music playing system and its player based on the location and the solar term synthesize the human vocal according to the frequency suitable for the user.

Another advantage of the present invention is to provide

Another advantage of the invention is to provide a music playing system and a player based on location and solar term, wherein the music playing system and the player based on location and solar term further obtain the information contained in the birthday according to the place of birth.

According to the present invention, the foregoing and other objects and advantages are attained by a music player based on a location and a solar term, comprising:
a processor;
a location acquisition device, used to obtain a current location;
a storage device;
a communication device;
a power supply device; and
a housing, wherein the processor, the location acquisition device, the storage device, the communication device and the power supply device are placed in the housing, wherein the processor is respectively communicatively connected to the location acquisition device, the communication device, the storage device and the power supply device, wherein the power supply device supplies an electrical energy to the processor, the location acquisition device, the communication device and the storage device, wherein the processor is obtained a birth date and is obtained a conditioning frequency used by a user for conditioning, wherein the processor is selected the music with the conditioning frequency according to a containing frequency for playing.

According to an embodiment of the present invention, the music player based on the location and the solar term further comprises a touch screen arranged in the housing, wherein the processor is communicatively connected to the touch screen, wherein the processor is received the birth date input by the touch screen.

According to an embodiment of the present invention, the processor further comprises a birth term determining device and a music selecting device, and the birth term determining device is communicatively connected with the music selecting device, wherein the birth term determining device determines a birth solar term according to the received birth date; the music selecting device obtains a conditioning frequency for conditioning according to the birth solar term, wherein the music selecting device selects a music with the conditioning frequency for playback according to the conditioning frequency for conditioning.

According to an embodiment of the present invention, the birth term determining device obtains a current location from the location acquisition device, wherein if the current location is in a Southern Hemisphere, the birth term determining device makes corresponding adjustments to the birth solar term in the Southern Hemisphere.

According to an embodiment of the present invention, the music selecting device further comprises a solar term scale acquiring device, a solar term frequency acquiring device and a selector, the selector is communicatively connected with the solar term scale acquiring device and the solar term frequency acquiring device, wherein the solar term scale acquiring device obtains an energy missing solar term according to the birth solar term, the solar term scale acquiring device obtains a body organ required for conditioning according to the energy missing solar term, and the solar term scale acquiring device obtains at least one conditioning scale according to the body organ that needs to be regulated; the solar term frequency acquiring device obtains at least one corresponding conditioning frequency according to at least one conditioning scale, wherein the selector selects the music with at least one conditioning frequency according to at least one conditioning frequency for playback.

According to an embodiment of the present invention, the solar term frequency acquiring device provides at least one musical instrument capable of producing at least one conditioning frequency for choice according to at least one conditioning frequency, the selector selects the music with at least one conditioning frequency for playback based on at least one conditioning frequency and the instrument that can produce at least one conditioning frequency.

According to an embodiment of the present invention, the music selecting device further comprises a music parser, the music parser is for analyzing a structural part of the music and whether each structural part of the music has a conditioning frequency, wherein the music parser analyzes at least one music with the conditioning frequency selected by the selector, and the music parser sorts at least one music with the conditioning frequency selected by the selector from most to least according to the number of structural parts with the conditioning frequency; from the music with the conditioning frequency, 24 pieces of music with the structural parts of the conditioning frequency are selected to form a conditioning playlist for playing.

According to an embodiment of the present invention, the music selecting device further comprises a generator, wherein the generator generates the instrument corresponding to at least one containing frequency according to at least one containing frequency, and generates at least one music with the conditioning frequency for playback.

According to an embodiment of the present invention, the touch screen is for displaying a user interface, wherein the user interface comprises a birth date portion for inputting a birth date, a location display portion for displaying a current location, a music display portion, wherein the music display portion is positioned on the bottom of the birth date portion and the location display portion for displaying twenty-four playlists with the name of the twenty-four solar terms.

According to an embodiment of the present invention, the user interface further comprises a constellation list display portion for displaying twelve constellations and corresponding solar terms.

For achieving the foregoing and other objects of the present invention, the present invention provides a music recommendation method based on a location and a solar term, performed by a computer, comprising one or more computers, comprising the steps as following:
A: Classify a selected music according to a five-note frequency, wherein step A further comprises the following steps:
   A1: Determine a frequency respectively corresponding to a five-note scale, wherein the five-note scale is a Gong scale, a Shang scale, a Jue scale, a Zhi scale and a Yu scale;
   A2: Select multiple pieces of music; and
   A3: Respectively determine a scale classification corresponding to the selected pieces of music, wherein the scale classification of the music is defined as one of the five-note scales corresponding to the frequency of one of the five-note scales that the music contains the largest number of;
B: Determine a birth solar term of a user according to a birth date of the user obtained from a user interface; and
C: Select the music suitable for the user among the music in the scale classification according to the birth solar term of the user by forming a label which is the same as the name of the birth date of the user at a user interface to commend the selected music to the user.

According to an embodiment of the present invention, the step A3 further comprises the following steps:
A31: Determine a number of structural parts contained in the selected music;
A32: Determine the frequency corresponding to the five-note scale of one of the largest numbers contained in each structural part of the selected music;
A33: Determine the scale classification of the structure part which is one of the corresponding five-note scale corresponding to the frequency corresponding to one of the largest number of the five-note scales according to the frequency corresponding to one of the largest number of the five-note scales; and
A34: Define the largest number of the scale classification of the selected structure parts as the scale classification of the selected music.

According to an embodiment of the present invention, the step B further comprises the following steps:
B1: Determine the corresponding dates of the twenty-four solar terms of a birth year of the user according to the birth date of the user; and
B2: Determine the birth solar term of the user, wherein the solar term of the date closest to the birth date of the user is taken as the birth solar term of the user.

According to an embodiment of the present invention, the step B further comprises the following steps:
B3: Determine whether it is in the Southern Hemisphere according to the current obtained location. If the current location is in the Southern Hemisphere, adjust the birth solar term of the user to match the solar term in the Southern Hemisphere.

According to an embodiment of the present invention, the step C further comprises the following steps:
C1: Determine an energy missing solar term according to the user's birth solar term;
C2: Determine a body organ required for conditioning according to the energy missing solar term;
C3: Determine the five-note scale used for conditioning the body organ according to the body organ required for conditioning;
C4: Select the music respectively corresponding to the five-note scale used for conditioning the body organ from the classified music, and form a conditioning playlist for playback.

For achieving the foregoing and other objects of the present invention, the present invention provides a music playing system based on a location and a solar term, comprising:
one or more processors; and
one or more storage devices, communicatively connected to the one or more processors, wherein the storage device comprises a computer readable instruction, the computer readable instruction is stored in the storage device, when the computer readable instruction is executed by the processor, causing the processor to perform the following operations, so as to:
classify a plurality of pieces of selected music according to corresponding frequencies of a five-note scale to create a five-note scale music classification, wherein the five-note scale is a Gong scale, a Shang scale, a Jue scale, a Zhi scale and a Yu scale;
determine a birth solar term of the user based on a user's obtained birth date; and
select a music suitable for the user among the five-note scale music classification according to the birth solar term of the user by forming a label which is the same as the name of the birth date of the user at a user interface to commend the selected music to the user for playback.

According to an embodiment of the present invention, the storage device further comprises the instruction, so as to:
Respectively determine the frequencies corresponding to the Gong scale, the Shang scale, the Jue scale, the Zhi scale and the Yu scale;
select multiple pieces of music;
determine the belonging scale classification of each of multiple pieces of music, wherein the scale classification is selected from one of the Gong scale, the Shang scale, the Jue scale, the Zhi scale and the Yu scale, wherein the five-note scale corresponding to the largest number of frequencies of one of the five-note scales contained in the music is regarded as the scale classification of the music.

According to an embodiment of the present invention, the storage device further comprises the instructions, so as to:
determine the number of structural parts comprised in the selected music;
determine the frequency corresponding to the five-note scale of one of the largest numbers contained in each structural part of the selected music;
determine the scale classification of the structure part which is one of the corresponding five-note scale corresponding to the frequency corresponding to one of the largest number of the five-note scales according to the frequency corresponding to one of the largest number of the five-note scales;
define the largest number of the scale classification of the selected structure parts as the scale classification of the selected music.

According to an embodiment of the present invention, the storage device further comprises the instructions, so as to
determine the corresponding dates of the twenty-four solar terms of a birth year of the user according to the birth date of the user; and
determine the birth solar term of the user, wherein the solar term of the date closest to the birth date of the user is taken as the birth solar term of the user.

According to an embodiment of the present invention, the storage device further comprises the instructions, so as to:
determine whether it is in the Southern Hemisphere according to the current obtained location. If the current location is in the Southern Hemisphere, adjust the birth solar term of the user to match the solar term in the Southern Hemisphere.

According to an embodiment of the present invention, the storage device further comprises the instructions, so as to:
determine an energy missing solar term according to the user's birth solar term;
determine a body organ required for conditioning according to the energy missing solar term;
determine the five-note scale used for conditioning the body organ according to the body organ required for conditioning; and
select the music respectively corresponding to the five-note scale used for conditioning the body organ from the classified music, and form a conditioning playlist for playback.

### BRIEF DESCRIPTION OF THE DRAWINGS

FIG. 1 is a schematic view of a classified user interface of a music playing system according to a preferred embodiment of the present invention.

FIG. 2 is a schematic view of a user interface of a music playing player according to the preferred embodiment of the present invention.

FIG. 3 is a schematic view of another user interface of the music playing player according to the preferred embodiment of the present invention.

FIG. 4 is a structural block diagram of the music playing player according to another preferred embodiment of the present invention.

FIG. 5 is a structural block diagram of the music playing system according to another preferred embodiment of the present invention.

FIG. 6 and FIG. 7 are flow charts of a music recommendation method for the music playing system according to the preferred embodiment of the present invention.

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

Those skilled in the art should understand that, in the disclosure of the present invention, terminologies of “longitudinal,” “lateral,” “upper,” “front,” “back,” “left,” “right,” “perpendicular,” “horizontal,” “top,” “bottom,” “inner,” “outer,” and etc. that indicate relations of directions or locations are based on the relations of directions or locations shown in the appended drawings, which are only to facilitate descriptions of the present invention and to simplify the descriptions, rather than to indicate or imply that the referred device or element is limited to the specific direction or to be operated or configured in the specific direction. Therefore, the above-mentioned terminologies shall not be interpreted as confine to the present invention.

It should be understood that the term “a” or “an” should be understood as “at least one” or “one or more”. In other words, in one embodiment, the number of an element may be one, and in another embodiment, the number of the element may be plural. The term “a” or “an” should not be understood as a limitation on the number.

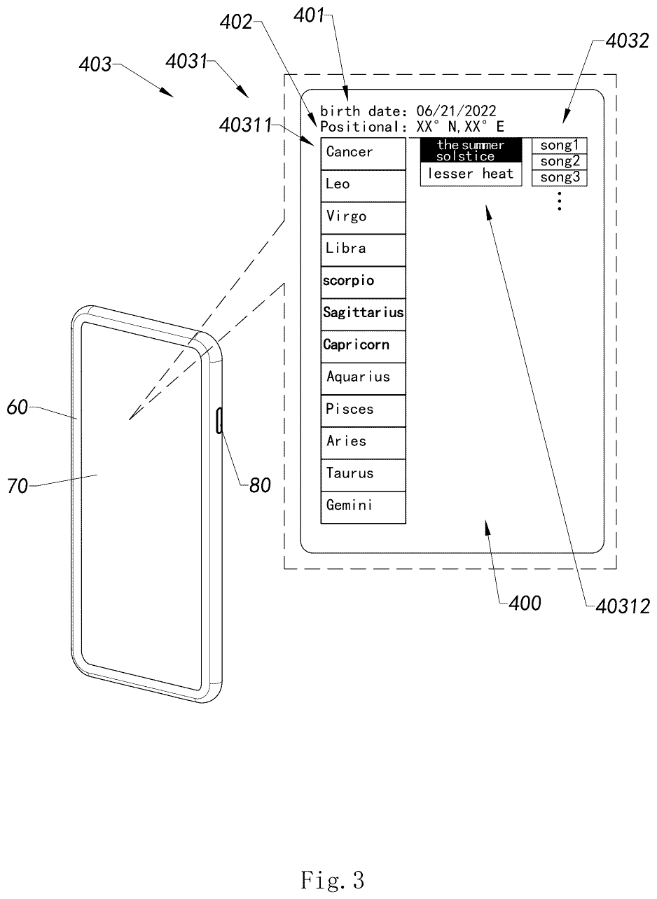

Referring to FIG. 3 of the structural block diagram, a music playing player based on a location and a solar term according to a preferred embodiment of the present invention. the music playing player based on the location and the solar term of the present invention comprises a location acquisition device 10, a storage device 20, a processor 30, a communication device 40 and a power supply 50. The processor 30 is respectively communicably connected with the location acquisition device 10, the storage device 20, the communication device 40 and the power supply 50. The power supply 50 is respectively provided an electrical energy to the location acquisition device 10, the storage device 20, the processor 30, and the communication device 40. Preferably, the power supply 50 is implemented as a rechargeable battery. The processor 30 obtains a current location information from the location acquisition device 10. The processor 30 selects a music to play based on the current location information. The location acquisition device 10 can be implemented as a GPS system, a BeiDou system, etc.

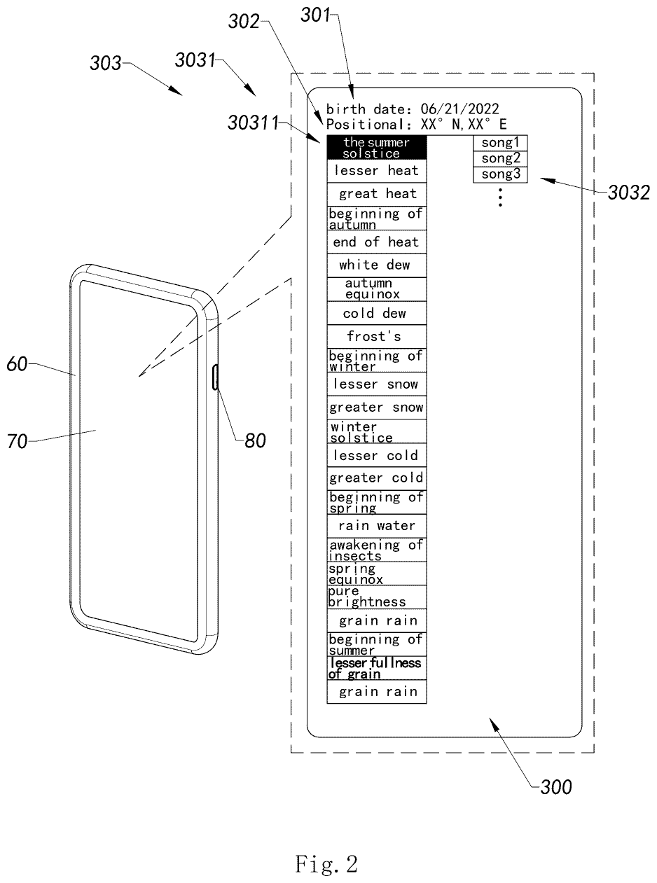

Referring to the FIG. 2 of the drawing, the music plater based on the location and the solar term comprises a housing 60, a touch screen 70, and a switch 80. The location acquisition device 10, the storage device 20, the processor 30, the communication device 40 and the power supply 50 are arranged within the housing 60. The touch screen 70 is arranged on one surface of the housing 60. The touch screen 70 is communicated with the processor 30. It is operated by the touch screen 70. The switch 80 is arranged on one side of the housing 60 for controlling the switch of the music player based on the location and the solar term of the invention. The communication device 40 is provided for being connected to the internet. The communication device 40 is further provided for being connected with a playback device. Such as a headphone, a speaker.

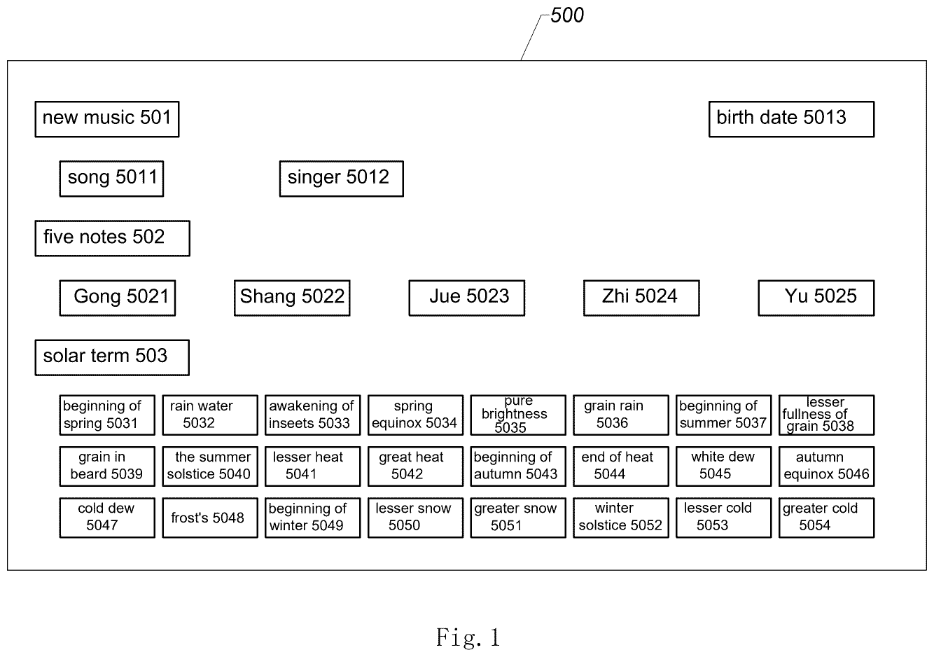

Referring to the FIG. 1 of the drawing, a user interface 300 of the music player based on the location and the solar term according to the present invention is illustrated. The user interface 300 further comprises a birth date portion 301 for the user to enter a birth date. The user interface 300 further comprises a location display portion 302 for displaying the current location information obtained by the location acquisition device 10. The user interface 300 further comprises a music display portion 303. Preferably, the music display portion 303 displays the music in the form of a playlist. It is worth mentioning that a label of the playlist is named after the twenty-four solar terms. The music display portion 303 further comprises a solar term playlist 3031 and a music name display portion 3032. The solar term playlist display portion displays the twenty-four solar term playlists 30311. When one of the solar term playlists 30311 is selected, the music name display portion 3032 is displayed with a corresponding music name 30321 in the form of the list.

Specifically, the user interface 300 displays on the touch screen 70. When the processor 30 obtains the user's birth date from the touch screen 70. That is, after the user enters the birth date through the birth date portion 301 of the user interface 300, the touch screen 70 transmits the birth date of the user to the processor 30. The processor 30 obtains the solar term closest to the user's birth date based on the user's birth date and current location information. The solar term closest to the user's birth date is defined as a user's birth solar term 3111. The processor 30 further uses the user's birth solar term as the birth solar term playlist 30311. Preferably, the label of the birth date is arranged on the top of the solar term label display portion 3031 by the processor 30. It is worth mentioning that the processor 30 takes the birth solar term list as a first list, and according to the order of the twenty-four solar terms, the remaining twenty-four solar term lists are displayed on the user interface 300 in the order of receiving the birth solar term.

Further, the processor 30 obtains the current location through the location acquisition device 10. The processor 30 selects the user interface according to the current location. For example, if the location acquisition device 10 obtains the current location of China. And the solar terms are reflected in the Chinese culture. The processor 30 selects the user interface 300 to be displayed on the touch screen 30. If the location acquisition device 10 for the United States, United Kingdom, Canada and other regions. Then select a constellation user interface 400. The solar term culture is not popular in these countries. Therefore, the processor 30 further assists in the constellations for understanding the solar term from the perspective of constellations. Specifically, the constellation user interface 400 further comprises a date portion 401 for inputting and displaying of the birth date. The constellation user interface further displays a location portion 402 for displaying the current location. The constellation user interface 400 further comprises a constellation list display portion 403 for displaying the constellation playlists. The constellation list display portion 403 displays the twelve constellation playlists 4031. Preferably, the constellation list display portion 403 shows the correspondence between the constellations and the solar terms.

The corresponding solar terms for Cancer are Summer Solstice and Minor Heat. The corresponding solar terms for Leo are Major Heat and Beginning of Autumn. The corresponding solar terms for Virgo are End of Heat and White Dew. The corresponding solar terms for Libra are Autumn Equinox and Cold Dew. The corresponding solar terms for Scorpio are Frost's Descent and Beginning of Winter. The corresponding solar terms for Sagittarius are Minor Snow and Major Snow. The corresponding solar terms for Capricornus are Winter Solstice and Minor Cold. The corresponding solar terms for Aquarius are Major Cold and Beginning of Spring. The corresponding solar terms for Pisces are Rain Water and Awakening of Insects. The corresponding solar terms for Aries are Spring Equinox and Pure Brightness. The corresponding solar terms of Taurus are Grain Rain and Beginning of Summer. The corresponding solar terms of Gemini are Grain Buds and Grain in Ear. The processor 30 is obtained the birth solar term 3111 of the user by analyzing the birth date of the user. The processor 30 obtains the constellation of the user based on the birth solar term 3111 of the user. The processor 30 is created the constellation user interface based on the user's birth solar term and the user's constellation. The processor 30 selects the corresponding music according to the user's birth solar term to add to the corresponding constellation playlist. It is worth mentioning that the processor 70 is placed the user's constellation playlist 4031 at the top. The constellation playlist 4031 is then arranged in order according to the constellation following the user constellation. The selected constellation playlist 4031 displays on the touch screen 70. The solar term and the music corresponding to the constellation playlist 4031 which are not selected are hidden. As shown in FIG. 2.

It is worth mentioning that the processor 30 obtains the birth date of the user after the user enters the birth date through the birth date portion 301. The processor 30 obtains the birth solar term 3111 of the user according to the user's birthday date. The processor 30 generates the playlist based on the user's birth solar term 3111, which is displayed in the music display portion 303.

It is worth mentioning that the processor 30 selects the solar term user interface 300 or the constellation user interface 400 of the solar term according to the user's location change. For example, the user is from China to United States. When the user departs in China, the processor 30 obtains the current location in China through the location acquisition device 10. The processor 30 selects the solar term user interface 300 displayed on the touch screen 70. When the user arrives in the United States, the processor 30 obtains the current location in the United States through the location acquisition device 10. The processor 30 selects the constellation user interface 400 to be displayed on the touch screen 70. Further, the processor 30 can change the selected music in the playlist according to the location change. For example, when the user is in China, the processor 30 obtains the current location in China through the location acquisition device 10, the processor 30 selects the music for the user according to the music in China, and then is added the selected music to the birth solar term playlist 30311. After the user arrives in the United States, the processor 30 acquires the current location in the United States according to the location acquisition device 10. The processor 30 searches for music in the United States to add to the constellation playlist 4031 corresponding to the user based on the information that the current location is the United States. Preferably, the selected American music is added to the constellation playlist 4031 corresponding to the user's birth solar term. In this preferred embodiment of the present invention, the change of the location can be pre-set by the user. For example, set that change the corresponding music of the playlist after the change of the city. For example, when the user moves from Guangzhou to Shenzhen, the processor 30 selects the music suitable for the user from the music in the Guangzhou region according to the current location of Guangzhou. The processor 30 is then added to the birth solar term playlist 30311 according to the selected music. When the user arrives in Shenzhen, the processor 30 acquires the current location in Shenzhen according to the location acquisition device 10. The processor 30 searches the music in the Shenzhen region to be selected the music suitable for the user. The processor 30 replaces the music selected in the Guangzhou region for playback based on the music selected in the Shenzhen region. In another preferred embodiment of the present invention, the processor 30 further creates the playlist for adding music selected according to the Shenzhen region. The user can further set the range of location changes, such as an administrative area of a city, a street, etc. If the user sets the update list to a region, such as a street, the user goes from that street to another street. The processor 30 obtains the current location by the location acquisition device 10. If the current location has entered another street, the processor 30 updates the playlist and will display with the music display portion 303.

The processor 30 further processes the relationship between the user's birth date and the twenty-four solar terms, thereby determining the frequency required by the user. Specifically, the processor determines the birth solar term 3111 of the user based on the date of the user's birthday. The processor 30 further obtains at least one energy missing solar term 3112 among the twenty-four solar terms according to the user's birth solar term 3111, so as to determine the body organs that need to be paid attention for conditioning. Preferably, the number of the energy missing solar term is six. The processor 30 further determines a respective musical note corresponding to the body organs requiring attention to conditioning according to the body organs requiring attention to conditioning. The processor 30 further determines the frequency of the pair frequency according to the respective musical notes corresponding to the body organs that the user needs to pay attention to conditioning. It is worth mentioning that due to the different seasons in the northern and southern hemispheres. Therefore, when judging the birth solar term, the processor 30 is needed to obtain the current location from the location acquisition device 10 to judge the birth solar term according to the current location.

The processor 30 further provides a method for obtaining the frequency required by the user, comprising the following steps:
A. Obtain a Gregorian calendar birth date of a user.
B. Determine a solar term closest to the user's birth date in the Gregorian calendar as a user's birth solar term 3111.
C. Determine the user's missing solar term energy which the user is missing.
D. Determine the corresponding musical note according to the user's missing user energy.
E. Determine the corresponding frequency according to the identified musical note

Among them, the date of the twenty-four solar terms in the Gregorian calendar is:
Beginning of Spring: February 4 or February 5. Rain Water: February 19 or February 20. Awakening of Insects: March 5 or March 6. Spring Equinox: March 20 or 21. Pure Brightness: April 4, April 5 or April 6. Grain Rain: April 20 or April 21. Beginning of Summer: May 5 or May 6. Grain Buds: May 21 or May 22. Grain in Ear: June 5 to June 6. Summer Solstice: June 21 or June 22. Minor Heat: July 7-July 8. Major Heat: July 22-July 23. Beginning of Autumn: August 7 or 8. End of Heat: August 23 or August 24. White Dew: September 7 or September 8. Autumnal Equinox: September 23 or September 24. Cold Dew: October 8 or October 9. Frost's Descent: October 23 or October 24. Beginning of Winter: November 7 or 8. Minor Snow: November 22 or 23. Major Snow: December 7 or December 8. Winter Solstice: December 22 or December 23. Minor Cold: January 5 or January 6. Major Cold: January 20 or January 21. It is worth mentioning that the dates of the above the twenty-four solar terms in the Gregorian calendar are based on the Northern Hemisphere. The twenty-four solar terms in the Southern Hemisphere are adapted to the opposite seasons in the Northern Hemisphere. Between step A and step B, further comprises step A′: Get the current location. Assist in determining the birth solar term 3111 of the user based on the current location. It is worth mentioning that in the present invention, definition that the person experiences about 280 days before birth, and experiences about 18 solar terms. In other words, there are 4 to 6 solar terms that have not been experienced before birth. A solar term not experienced before birth is defined as the energy missing solar term 3112.

Among them, if the user's birth solar term 3111 is Major Snow, then the user's energy missing solar terms 3112 are Winter Solstice, Minor Cold, Major Cold, Beginning of Spring, Rain Water and Awakening of Insects. The users need to pay attention to the conditioning of kidney, bladder, spleen-stomach, liver-gallbladder.

If the user's birth solar term 3111 is Minor Snow, then the user's missing energy terms 3112 are Major Snow, Winter Solstice, Minor Cold, Major cold, Beginning of Spring, and Rain Water. The users need to pay attention to the conditioning of kidney, bladder, spleen-stomach, liver, and gallbladder.

If the user's birth solar term 3111 is the Beginning of Winter, then the user's energy missing solar terms 3112 are Minor Snow, Major Snow, Winter Solstice, Minor Cold, Major cold, and Beginning of Spring. The users need to pay attention to the conditioning of kidney, bladder, spleen-stomach, liver-gallbladder.

If the user's birth solar term 3111 is Frost's Descent, then the user's energy missing solar terms 3112 are Beginning of Winter, Minor Snow, Major Snow, Winter Solstice, Minor Cold, and Major Cold. The users need to pay attention to the conditioning of kidney, bladder, spleen-stomach.

If the user's birth solar term 3111 is Cold Dew, then the user's energy missing solar terms 3112 are Frost's Descent, Beginning of Winter, Minor Snow, Major Snow, Winter Solstice and Minor Cold. The users need to pay attention to the conditioning of spleen-stomach, kidney, bladder.

If the user's birth solar term 3111 is Autumn Equinox, then the user's energy missing solar terms 3112 are Cold Dew, Frost's Descent, Beginning of Winter, Minor Snow, Major Snow and Winter Solstice. The users need to pay attention to the conditioning of lung, large intestine, spleen-stomach, kidney and bladder.

If the user's birth solar term 3111 is White Dew, then the user's energy missing solar terms 3112 are Autumn Equinox, Cold Dew, Frost's Descent, Beginning of Winter, Minor Snow and Major Snow. The users need to pay attention to the conditioning of lung, large intestine, spleen-stomach, kidney and bladder.

If the user's birth solar term 3111 is End of Heat, then the user's energy missing solar terms 3112 are White Dew, Autumn Equinox, Cold Dew, Frost's Descent, Beginning of Winter and Minor Snow. The users need to pay attention to the conditioning of lung, large intestine, spleen-stomach, kidney and bladder.

If the user's birth solar term 3111 is Beginning of Autumn, then the user's energy missing solar terms 3112 are End of Heat, White Dew, Autumn Equinox, Cold Dew, Frost's Descent and Beginning of Winter. The users need to pay attention to the conditioning of lung, large intestine, spleen-stomach, kidney and bladder.

If the user's birth solar term 3111 is Major Heat, then the user's energy missing solar terms 3112 are Beginning of Autumn, End of Heat, White Dew, Autumn Equinox, Cold Dew and Frost's Descent. The users need to pay attention to the conditioning of lung, large intestine and spleen-stomach.

If the user's birth solar term 3111 is Minor Heat, then the user's energy missing solar terms 3112 are Major Heat, Beginning of Autumn, End of Heat, White Dew, Autumn Equinox and Cold Dew. The users need to pay attention to the conditioning of lung, large intestine and spleen-stomach.

If the user's birth solar term 3111 is Summer Solstice, then the user's energy missing solar terms 3112 are Minor Heat, Major Heat, Beginning of Autumn, End of Heat, White Dew and Autumn Equinox. The users need to pay attention to the conditioning of heart, small intestine, spleen-stomach, lung and large intestine.

If the user's birth solar term 3111 is Grain in Ear, then the user's energy missing solar terms 3112 are Summer Solstice, Minor Heat, Major Heat, Beginning of Autumn, End of Heat and White Dew. The users need to pay attention to the conditioning of heart, small intestine, spleen-stomach, lung and large intestine.

If the user's birth solar term 3111 is Grain Buds, then the user's energy missing solar terms 3112 are Grain in Ear, Summer Solstice, Minor Heat, Major Heat, Beginning of Autumn and End of Heat. The users need to pay attention to the conditioning of heart, small intestine, spleen-stomach, lung and large intestine.

If the user's birth solar term 3111 is Beginning of Summer, then the user's energy missing solar terms 3112 are Grain Buds, Grain in Ear, Summer Solstice, Minor Heat, Major Heat and Beginning of Autumn. The users need to pay attention to the conditioning of heart, small intestine, spleen-stomach, lung and large intestine.

If the user's birth solar term 3111 is Grain Rain, then the user's energy missing solar terms 3112 are Beginning of Summer, Grain Buds, Grain in Ear, Summer Solstice, Minor Heat and Major Heat. The users need to pay attention to the conditioning of heart, small intestine, and spleen-stomach.

If the user's birth solar term 3111 is Pure Brightness, then the user's energy missing solar terms 3112 are Grain Rain, Beginning of Summer, Grain Buds, Grain in Ear, Summer Solstice and Minor Heat. Th users need to pay attention to the conditioning of spleen-stomach, heart, and small intestine.

If the user's birth solar term 3111 is Spring Equinox, then the user's energy missing solar terms 3112 are Pure Brightness, Grain Rain, Beginning of Summer, Grain Buds, Grain in Ear and Summer Solstice. The users need to pay attention to the conditioning of liver, gallbladder, spleen-stomach, heart, and small intestine.

If the user's birth solar term 3111 is Awakening of Insects, then the user's energy missing solar terms 3112 are Spring Equinox, Pure Brightness, Grain Rain, Beginning of Summer, Grain Buds and Grain in Ear. The users need to pay attention to the conditioning of liver, gallbladder, spleen-stomach, heart, and small intestine.

If the user's birth solar term 3111 is Rain Water, then the user's energy missing solar terms 3112 are Awakening of Insects, Spring Equinox, Pure Brightness, Grain Rain, Beginning of Summer and Grain Buds. The users need to pay attention to the conditioning of liver, gallbladder, spleen-stomach, heart, and small intestine.

If the user's birth solar term 3111 is Beginning of Spring, then the user's missing solar terms 3112 are Rain Water, Awakening of Insects, Spring Equinox, Pure Brightness, Grain Rain and Beginning of Summer. The users need to pay attention to the conditioning of liver, gallbladder, spleen-stomach, heart, and small intestine.

If the user's birth solar term 3111 is Major Cold, then the user's energy missing solar terms 3112 are Beginning of Spring, Rain Water, Awakening of Insects, Spring Equinox, Pure Brightness and Grain Rain. The users need to pay attention to the conditioning of liver, gallbladder, and spleen-stomach.

If the user's birth solar term 3111 is Minor Cold, then the user's energy missing solar terms 3112 are Major Cold, Beginning of Spring, Rain Water, Awakening of Insects, Spring Equinox and Pure Brightness. The users need to pay attention to the conditioning of liver, gallbladder, and spleen-stomach.

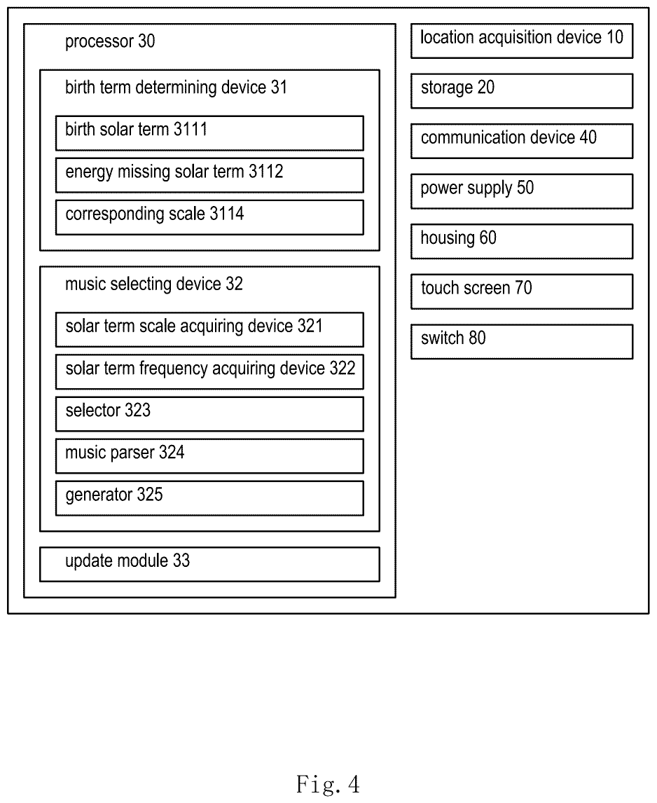

If the user's birth solar term 3111 is Winter Solstice, then the user's energy missing solar terms 3112 are Minor Cold, Major Cold, Beginning of Spring, Rain Water, Awakening of Insects and Spring Equinox. The users need to pay attention to the conditioning of kidneys, bladder, liver, gallbladder, and spleen-stomach.

Where, if the location acquisition device 10 obtains the current location in Europe, the United States, the Canada and other Western countries, the processor 30 further processes the relationship between the solar terms and the constellation. The processor 30 first determines the user's birth solar term 3111 based on the user's birth date. The processor 30 further determines the constellation of the user based on the birth solar term 3111 of the user. If the birth date of the user is at the junction of two constellations, if the birth date is before the corresponding solar term, the user belongs to the previous constellation; if the birth date is after the corresponding solar term, the user belongs to the latter constellation. Referring to the FIG. 4 shows another constellation user interface 400 of the player based on the location and the solar term of the invention, wherein the constellation user interface 400 is added according to the relationship between the constellation and the solar term.

The processor 30 further determines a scale corresponding to the body organ that requires attention to conditioning. Taking ancient Chinese music as an example, the scale that is beneficial to the heart is the Zhi music, corresponding to the “5” in the numbered musical notation. The scale that is favorable to the liver is the Jue tone, corresponding to the “3” in the numbered musical notation. The scale that are beneficial to the spleen is Gong music, corresponding to the “1” in the numbered musical notation. The scale that is beneficial to the lung is the Shang music, corresponding to the “2” in the numbered musical notation. The scale that is beneficial to the kidney is the Yu music, corresponding to the “6” in the numbered musical notation. The music can infect, regulate emotions, and then affect the body. Letting the emotionally excited one listen to the peaceful and sad music, can adjust the mood, such as, taking away the sadness with the sobbing music, and venting the over-excited emotions with the fast-paced music. In order to be suitable for the creation of music, the change Gong is introduced, corresponding to the “4” in the numbered musical notation. The change Zhi is introduced, corresponding to the “7” in the numbered musical notation.

The processor 30 further determines the corresponding scale frequency according to the scale. For example, C scales 1,2,3,4,5,6,7,1 respectively correspond to frequencies of 261.6, 293.7, 329.6, 349.2, 392.0, 440.0, 493.9, 523.2. The processor 30 selects the corresponding musical instrument according to the frequency and is generated the music. In an alternative embodiment, the processor 30 selects the music with the most applicable frequencies among the existing music to play.

In particular, the processor 30 further comprises a birth term determining device 31 and a music selecting device 32. The music selecting device 32 is communicatively connected with the birth term determining device 31. The birth term determining device 31 obtains the birth date of the user by obtaining the birth date from the touch screen 70. The birth term determining device 31 determines the birth solar term 3111 of the user through the birth date of the user. The music selecting device 32 generates the music required by the user according to the user's birth solar term 3111. The music selecting device 32 further comprises a solar term scale acquiring device 321, a solar term frequency acquiring device 322 and a selector 323. The solar term scale acquiring device 321 is respectively communicated with the birth term determining device 31, the solar term frequency acquiring device 322 and the selector 323. The solar term scale acquiring device 321 acquires the birth solar term 3111 of the user from the birth term determining device 31. The term closest to the user's birth date is defined as the user's birth solar term 3111. The solar term scale acquiring device 321 further obtains the energy missing solar term 3112 based on the birth solar term of the user. The solar term scale acquiring device 31 obtains the information about the body organs that the user needs to pay attention to by means of the user's energy missing solar term. The solar term scale acquisition device 31 further obtains a corresponding scale 3114 that can be used to adjust the user's body organs according to the information of the body organs that need attention to be conditioned. The selector 323 is communicated with the location acquisition device 10 to obtain the current location. The selector 323 selects the music popular in the area of the current location in the internet through the communication device 40 according to the current location. The selector 323 further selects the music containing the solar term scale among the music selected in the region where the current location is located. The selector 323 adds the music containing the solar term scale selected from the region where the current location is located to the birth solar term playlist 30311. Preferably, the selector 323 will further select the music with the large number solar term scales from the selected popular music in the region where the current location is located, and further select the twenty-four pieces among them as the music comprised in the birth solar term playlist 30311. It is worth mentioning that the music contained in the birth solar term list can be downloaded to the storage device 20 through the communication device 40. It is worth mentioning that the birth solar term playlist 30311 is further contained the information of the current location.

The selector 323 further selects the music according to the frequency suitable for the user. Specifically, the solar term frequency acquiring device 322 obtains the corresponding musical scale 3111 (3114?) from the solar term scale acquiring device 321 for conditioning the user's body organs. The solar term frequency acquiring device 322 obtains the frequency corresponding to the user's body organs according to the corresponding musical scale 3111 used for conditioning the user's body organ. For example: frequency range (Hz): 16 k-20 k, can be used the overtone of the instruments, such as electronic ensemble, Chinese Zither, piano. Frequency range (Hz): 12 k-16 k, can be used the high-frequency overtones of the instruments, such as bell, tambourine, triangle percussion. Frequency range (Hz): 8 k-12 k, can be used the overtone of the instruments, such as flute, oboe, trumpet, piccolo. Frequency range (Hz): 4 k-8 k, can be used some female voices, and most of the wind instruments. Frequency range (Hz): 2 k-4 k, can be used some female voices, and most of the wind instruments. Frequency range (Hz): 800, can be used voice, and some percussion instruments. Frequency range (Hz): 300-500, can be used voice. Frequency range (Hz): 150-300, can be used male voice. Frequency range (Hz): 60-100, can be used the instruments, such as drum, cello, tuba. The solar term frequency acquiring device is 322 further adapted to be provided the instrument emitting the corresponding frequency according to the frequency corresponding to the body organ of the user for conditioning so that the music can be selected according to the type of instrument. That is, the selector 323 is provided for the selection of music according to frequencies corresponding to the body organs used for conditioning the user. The selector 323 is further provided for the selection of the instrument capable of producing a frequency corresponding to the user's body organs for conditioning, and then the selection of music based on the frequency emitted by the selected instrument.

The music selecting device 32 further comprises a music parser 324. The music parser 324 of structure analyzes the structure of music. For example, the structure of A piece of music is analyzed into overture, prelude, part A, part B1, part B2 and the postlude. For example, one song is divided into intro, verse, chorus, bridge, outro, and independent interlude. That is, the music parser 324 is provided for dividing music into multiple structural parts. The music selected by the selector 323 according to the frequency corresponding to the body organs of the user used for conditioning is transmitted to the music parser 324. The music selected according to the frequencies used to condition the user's body organs is defined as the selected music.

The music parser 324 further separately analyzes whether each structural part of the selected music contains the frequencies for conditioning the user's body organs. The music parser 324 counts the number of the structural parts in the selected music that comprise the frequencies for conditioning the user's body organs. The selector 323 selects the selected music with the large number of the structural parts containing the frequencies for conditioning the user's body organs. For example: the selector 32 selects three pieces of music. The music parser 324 divides the first piece of music into five structural parts, the second piece of music into four structural parts, and the third piece of music into four structural parts. The music parser 324 analyzes the first piece of music in which three structural parts contain the frequencies for conditioning the user's body organs. The music parser 324 analyzes the second piece of music in which four structural parts contain the frequencies for conditioning the user's body organs. The music parser 324 analyzes the third piece of music in which only one structural part contains the frequency for conditioning the user's body organs. That is, of the three pieces of music, the second piece of music contains the largest number of frequencies required for conditioning the user's body organs. The selector 323 preferentially selects the second music to be added to the birth solar term playlist 30311. The second choice is the first music. If the birth solar term playlist 30311 has only two music locations left. Then the selector 323 selects the second music and the first music. That is, the music with the large number of structural parts containing the frequencies required for the conditioning of the user's body organs preferentially selects by the selector 323.

The music selecting device 32 further comprises a generator 325 for generating the frequencies containing the frequencies used for conditioning the body organs of the user. The generator 325 first selects the type of music, and then determines the number of structural parts that the selected music has based on the type of music. The generator 325 selects the corresponding instrument or voice for each part of the structure according to the frequency used to condition the user's body organs. The generator 325 then generates each structural part according to the selected instrument, the voice, and according to the frequency used for conditioning the user's body organs. The generator 325 integrates each structural part to form the piece of music containing the frequencies for conditioning the user's body organs.

The processor 30 further comprises an update module 33. The update module 33 is communicatively connected to the location acquisition device 10. The update module 33 can update music in a playlist by default based on the location changes. The update module 33 is provided the option to update comprising the update by the change of the venue, such as library, fitness room, study room, etc. The update module 36 is provided the update options comprising the update by the change of the region, such as street, administrative district, city, etc., and is also provided a user customization. Take the example of updating the playlist by venue for further illustration. The present invention is the music player based on the location and the solar term that is playing a song on the playlist. The location acquisition device 10 detects that the user has entered a gym based on the current location information. The update module 33 transmits the information entering the gym to the music selecting device 35. The music selecting device 35 converts the music into one suitable for playing during exercise by the information that is in the gym. That is, the music selecting device 35 further selects the selected music conducive to the user's conditioning of scales, frequencies between the sounds and/or instruments from the music suitable for playing during exercise to form an exercise playlist. The update module 33 updates the exercise playlist for playback while exercising.

Specifically, the user enters the birth date of the user as Jun. 27, 1990 through the touch screen 70. At this point, the location entered by the user is China, located in the Northern Hemisphere. The birth term determining device 31 analyzes the nearest solar term with June 27 as the Summer Solstice. The solar term scale acquiring device 321 determines that the birth solar term of the user is the Summer Solstice. Further, the solar term scale acquiring device 321 analyzes that the corresponding energy missing solar terms of the birth solar term of the Summer Solstice are Minor Heat, Major Heat, Beginning of Autumn, End of Heat, White Dew and Autumn Equinox. The solar term scale acquiring device 321 is needed to pay attention to regulating the heart, small intestine, spleen-stomach, lung and large intestine according to the solar term of the user's missing energy. The solar term scale acquiring device 321 is paid attention to the information of regulating the heart, small intestine, spleen-stomach, lung and large intestine according to the need, and is obtained the scale used for regulating the heart as the Zhi music, the numbered musical notation is “5”; The scale used for regulating the lung is Shang music, and the numbered musical notation is “6”; The scale used for regulating the spleen is Gong music, and the numbered musical notation is “1”. The solar term frequency acquiring device 322 obtains the corresponding frequencies are respectively 392.0 Hz, 440.0 Hz and 261.6 Hz according to the numbered musical notation 5, 6 and 1. The solar term frequency acquiring device 322 is provided the selection of the instruments capable of emitting these frequencies of 392.0 Hz, 440.0 Hz and 261.6 Hz. The selector 323 selects at least one piece of music according to the selected instrument and the numbered musical notation “5, 6 and 1” corresponding to the scales that facilitate for regulating of the user. The music parser 324 analyzes at least one piece of selected music, respectively obtaining the number of structural parts of the piece of selected music. The music parser 324 further analyzes whether each part of the structure of the selected music containing 392.0 Hz, 440.0 Hz and 261.6 Hz. The music parser 324 counts the number of structural parts containing 392.0 Hz, 440.0 Hz, and 261.6 Hz in the selected music. The selector 323 preferentially selects the music with the large number of the structure part of 392.0 Hz, 440.0 Hz and 261.6 Hz and is updated the music to the playlist for playback.

It is worth mentioning that the music selecting device 34 can select multiple pieces of music to form at least one playlist. Preferably, the number of songs per playlist is limited to 24. The playlist is then updated for playback.

The generator 325 can form the playlist by generating the numbered musical notation “5, 6, 1” corresponding to the scale conducive to the user's regulating. In particular, the generator 325 obtains the numbered musical notation “5, 6, 1” corresponding to the scale that is conducive to the user's regulating from the solar term scale acquiring device 321. The generator 325 obtains the frequencies corresponding to the numbered musical notation “5, 6, 1” and the instrument capable of producing the frequencies corresponding to the numbered musical notation “5, 6, and 1” from the solar term frequency acquiring device 322. The selected generator 325 determines the structural part of the generated music through the music parser 324. The generator 325 forms at least one conditioned music for playback according to the structural part of the generated music, the numbered musical notation “5, 6 and 1” corresponding to the scale conducive to user's regulating and the corresponding frequency, and the instrument capable of providing the corresponding frequency. If the user walks into the gym, the update module 36 adds the information played during the exercise to the music selecting device 32. The music selecting device 35 re-selects the played music for regulating according to the playing in the exercise, forming at least one exercise playlist for the player to play.

In another preferred embodiment of the present invention, the music parser 324 further provides for the analysis for a tone of music. For example, identify the tone of a piece of music as the key C. The music parser 324 can identify the tone of the music as key C, key D, key E, key G and key A, etc. The music parser 324 sends the music and corresponding tones to the generator 325. The generator 325 adds a tone identifier to the musical name corresponding to the music for identification. For example, the tone of the music is Key C, and the musical name of the music is “sky”. The generator 325 adds the tone identifier “Key C” to the musical name “sky” of the music, and the musical name of the music becomes “sky. Key C” . In such a way, when the music parser 324 recognizes a piece of music, the music parser 324 first recognizes the name of the music. If the music name has the musical name, the music parser 324 recognizes the tone identifier contained in the music name. It is worth mentioning that the generator 325 classifies the music according to the tone identifier. The generator 325 classifies the key C as “Gong”, the key D as “Shang”, the key E as “Jue”, the key G as “Zhi”, and the key A as “Yu”. Preferably, the generator 325 defines an alias for the music category. Specifically, the alias of “Gong” is “earth”, the alias of “Shang” is “metal”, the alias of “Jue” is “wood”, the alias of “Zhi” is “fire”, the alias of “Yu” is “water”. In this way, the update module 33 classifies the newly added music into one of the five notes. In other words, if the newly added music is “sky. Key C” The updated module 33 classifies the newly added music into the Gong note. The newly added music “Sky. Tone” is displayed in the corresponding playlist.

It is worth mentioning that the user can query the corresponding music through the classification of the five notes scale. For example, when the user clicks on a label 502 of a user interface 500, the generator 325 selects the music classified as the Gong in five notes and displays it in the corresponding playlist for playback.

Referring to the FIG. 4 of the drawing, a block diagram of a music playing system based on a location and a solar term according to another preferred embodiment of the present invention is illustrated. The music playing system based on the location and the solar term of the present invention comprises a storage module 20A, a music module based on a solar term 30A, a communication module 40A and an operation module 50A. In the preferred embodiment of the present invention, the music playing system based on the location and the solar term of the present invention is implemented in the form of a cloud server. Wherein the storage module 20A, the music module based on the solar term 30A, and the communication module 40A are arranged on at least one cloud server 50A. The operation module 50 is installed on at least one intelligent terminal 60A. In another preferred embodiment of the present invention, the intelligent terminal 60A is defined as computer, tablet computer, smart phone, smart watch, smart glasses, etc. The operation module 50A obtains the current location information through the installed intelligent device, and then transmits the current location information to the music module based on the solar term 30A through the intelligent terminal 60A. The operation module 50A is installed on the intelligent terminal 60A. The operation module 50A can use the user interface 300 as shown in FIG. 1. Through the operation module 50A, the user interacts with the music playing system based on the location and the solar term of the invention.

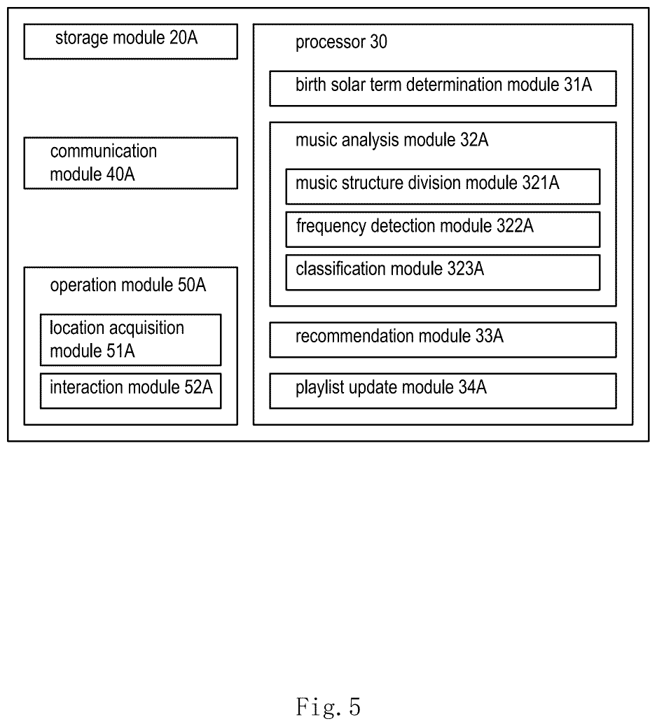

In a preferred embodiment of the present invention, the music module based on the solar term 30A classifies the music according to five notes. In the present invention, the five notes are defined as: Gong, Shang, Jue, Zhi and Yu. The numbered musical notation corresponding to the Gong is “1”. The numbered musical notation corresponding to the Shang is “2”. The numbered musical notation corresponding to the Jue is “3”. The numbered musical notation corresponding to the Zhi is “5”. The numbered musical notation corresponding to the Yu is “6”. In the key C, the numbered musical notation “1” corresponds to a frequency of 261.6 Hz. The numbered musical notation “2” corresponds to a frequency of 293.7 Hz. The numbered musical notation “3” corresponds to a frequency of 329.6 Hz. The numbered musical notation “5” corresponds to a frequency of 392.0 Hz. The numbered musical notation “6” corresponds to a frequency of 440.0 Hz. The music module based on the solar term 30A classifies the music according to five notes. The music module based on the solar term 30A detects the number of frequencies in each music that are respectively contained in the five notes, and defines the five notes of the frequency with the largest number as the music classification. For example, in a piece of music, the music module based on the solar term 30A detects that the frequency of the Gong in the music is 5 and the frequency of the Shang in the music is 4. The music module based on the solar term 30A classifies the music as Gong. It is worth mentioning that the music module based on the solar term 30A can detect the tone of the music, and then select the corresponding frequency of the five notes according to the tone to respectively detect the music. The music module based on the solar term 30A stores the categorized music in the storage module 20A. The classified user interface shown in FIG. 5 further comprises a five-note classification portion. The user clicks on the classified user interface to display the corresponding music.

The music module based on the solar term 30A associates the five-note scale with the solar term. The music module based on the solar term 30A is defined as follows: the corresponding solar terms of Yu are Beginning of Winter, Minor Snow, Major Snow, Winter Solstice and Minor Cold. The corresponding solar terms of Gong are Major Cold, Grain Rain, Major Heat and Frost's Descent. The corresponding solar terms of Jue are Beginning of Spring, Rain Water, Awakening of Insects, Spring Equinox, and Pure Brightness. The corresponding solar terms of Zhi are Beginning of Summer, Grain Buds, Grain in Ear, Summer Solstice and Minor Heat. The corresponding solar terms of Shang are Beginning of Autumn, End of Heat, White Dew, Autumn Equinox and Cold Dew.

The operation module 50A sends the received user's birth date to the music module based on the solar term 30A. The music module based on the solar term 30A obtains the user's birth solar term 3111 according to the user's birth date. The music module based on the solar term 30A selects the corresponding music classification of the birth solar term according to the user's birth solar term to recommend the corresponding music classification to the user. For example, if the user's birth date corresponds to the birth solar term 3111 is Summer Solstice. The music module based on the solar term 30A is characterized by the five notes corresponding to Summer Solstice. The music module based on the solar term 30A recommends the Zhi music for the user.

The music module based on the solar term 30A further comprises a music analysis module 32A, a birth solar term determination module 31A, and a recommendation module 33A. The music analysis module 32A is communicatively connected with the birth solar term determination module 31A and the recommendation module 33A. The music analysis module 32A is provided for classifying music. The birth solar term determination module 31A receives the birth date of the user. The birth solar term determination module 31A determines the birth solar term 3111 of the user based on the user's birth date. The recommendation module 33A selects the music from one of the music classifications of the classified music to recommend to the user according to the birth solar term 3111 of the user.

The music analysis module 32A provides the classification according to the five notes. Specifically, the music analysis module 32A classifies the music according to the five-note scale. That is, if one of the five-note scales is the majority in the music, the music analysis module 32A classifies the music as the scale with the most five-note scales. For example, if a piece of music has the largest number belonging to the Gong scales, the music is classified into the Gong scale.

The music analysis module 32A further comprises a music structure division module 321A, a frequency detection module 322A and a classification module 323A. The classification module 323A is respectively communicatively connected with the music structure division module 321A and the frequency detection module 322A. The music structure division module 321A analyzes the structural parts of the music, such as dividing a piece of music into multiple structural parts, such as prelude, part A, part B, etc. The frequency detection module 322A respectively detects the frequencies corresponding to the five-note scale contained in the music. Further, the frequency detection module 322A respectively analyzes each structural part of the music according to the respectively corresponding frequencies of the five-note scales to obtain the number of the five-note scales respectively included in each structural part of the music. The five-note scale with the largest number in the structural part is defined by the classification module 323A as the five-note scale of the structural part. The classification module 323A classifies the music into the large number of structural parts of the same classification of five-note scales. For example, the music structure division module 321A divides the music into five structural parts. The frequency detection module 322A respectively detects the five structural parts according to the frequencies corresponding to the five-note scale, and obtains that the first structural part of the music consists of three Gong scales and two Yu scales; the second structural part of the music comprises two Zhi scales, one Yu scale and one Gong scale; the third structural part of the music comprises one Shang scale and three Gong scales; the fourth structural part of the music comprises two Jue scales and three Gong scales, and the fifth structural part of the music comprises two Jue scales. The classification module 323A classifies the first structural part of the music into Gong scales. The classification module 323A classifies the second structural part of the music into Zhi scale. The classification module 323A classifies the third structural part of the music into Gong scale. The classification module 323A classifies the fourth structural part of the music into Gong scale. The classification module 323A classifies the fifth structural part of the music into Jue scale. Since of the five structural parts of the music, the first structural part, the third structural part, and the fourth structural part are classified as the Gong scale. The second structural part is classified as the Zhi scale. The fifth structural part is classified as the Jue scale. Therefore, the classification module 323A classifies the music as the Gong scale. In this way, the classification module 323 classifies several pieces of music as Gong, Shang, Jue, Zhi and Yu respectively. The musical classifications of Gong, Shang, Jue, Zhi and Yu are shown as Gong 5021, Shang 5022, Jue 5023, Zhi 5024 and Yu 5025 respectively in the FIG. 1. If the user clicks the Gong 5021 icon, the music classified by Gong 5021 can be played.

It is worth mentioning that the music analysis module 32A provides another music classification method, the solar term classification method. Specifically, the scales corresponding to Winter Solstice are: Yu, Jue and Gong. The scales corresponding to Minor Cold are Jue and Gong. The scales corresponding to Major cold are Jue and Gong. The scales corresponding to Beginning of spring are Jue, Gong and Zhi. The scales corresponding to Rain Water are Jue, Gong and Zhi. The scales corresponding to Awakening of Insects are Jue, Gong and Zhi. The scales corresponding to Spring Equinox are Jue, Gong and Zhi. The scales corresponding to Pure Brightness are Gong and Zhi. The scales corresponding to Grain Rain are Gong and Zhi. The scales corresponding to Beginning of Summer are Gong and Zhi. The scales corresponding to Grain Buds are Gong, Zhi and Shang. The scales corresponding to Grain in Ear are Gong, Zhi and Shang. The scales corresponding to Summer Solstice are Gong, Zhi and Shang. The scales corresponding to Minor Heat are Gong and Shang. The scales corresponding to Major Heat are Gong and Shang. The scales corresponding to Beginning of Autumn are Gong and Shang. The scales corresponding to End of Heat are Gong and Shang. The scales corresponding to White Dew are Gong, Shang and Yu. The scales corresponding to Autumnal Equinox are Gong, Shang and Yu. The scales corresponding to Cold Dew are Gong and Yu. The scales corresponding to Frost's Descent are Gong and Yu. The scales corresponding to Beginning of Winter are Gong and Yu. The scales corresponding to Minor Snow are Gong, Yu and Jue. The scales corresponding to Major Snow are Gong, Yu and Jue.

According to the corresponding scales of each solar term, the classification module 323A selects the music of the corresponding scales of each solar term from the music categorized as Gong, Shang, Jue, Zhi and Yu respectively to classify the music into the corresponding solar term. For example, the Winter Solstice solar term music is classified. The classification module 323A selects from the music classified as Gong, Shang, Jue, Zhi and Yu to classify the music of Yu, Jue and Gong into the Winter Solstice classification. The remaining twenty-three solar terms are classified in this way.

The birth solar term determination module 31A determines the birth solar term 3111 of the user based on the birth date of the user received. The recommendation module 33A selects the music suitable for the user to recommend according to the classification of music by the birth solar term 3111 of the user and the classification module 323A. For example, the birth solar term determination module 31A determines that the birth solar term 3111 of the user is Summer Solstice. The corresponding scales of the Summer Solstice are Gong, Zhi and Shang. The recommendation module 33A selects the music suitable for the user from the Gong scale, Zhi scale and Shang scale classified by the classification module 323A. The recommendation module 33A further generates a recommendation playlist 331A based on the selected music. It is worth mentioning that the recommendation module 33A can select music from the classification of the Summer Solstice to recommend to the user according to the classification module 33A of the solar term classification. The recommendation module 33A forms the recommended playlist 331A from the selected music classified by the solar term to recommend to the user.

Referring to the FIG. 1 of the drawing, a classified user interface according to a preferred embodiment of the present invention is illustrated. The classified user interface 500 further comprises a new music 501 for displaying the newly added music. The new music 501 further comprises a song 5011 and a singer 5012. The added new music is categorized by musical name and singer respectively, to correspond to the song 5011 and singer 5012 in the classified user interface 500. The classified user interface 500 further comprises a five-note 502 for displaying five-note classifications. The Gong, Shang, Jue, Zhi and Yu categories correspond to five labels Gong 5021, Shang 5022, Jue 5023, Zhi 5024 and Yu 5025 respectively. The classified user interface 500 further comprises a solar term 503 for displaying the classification of solar term music. The solar term 503 further illustrates the music classification of the twenty-four solar terms. The classification of the twenty-four solar terms is respectively represented by the names of the solar terms. Such as Beginning of Spring 5031, Rain Water 5032, Awakening of Insects 5033 and so on.

The classified user interface 500 further comprises a birth date 5013 for entering the user's birth date. When the user enters the birth date, the music analysis module 32A classifies the music according to the birth date of the user, and then connects the classified music to the corresponding five-note classification and solar term classification. The user plays the corresponding music by clicking the corresponding music classification. For example, the user clicks on Winter Solstice 5052 to play music classified as Winter Solstice. It is worth mentioning that after the birth solar term determination module 31A determines the birth solar term of the user, the classified user interface 500 only displays the solar term classification corresponding to the birth solar term of the user. For example, the user's birth solar term is Beginning of Autumn, then the classified user interface 500 only displays the music classification of Beginning of Autumn 5043.

The operation module 50A is used to control the intelligent terminal to display the user interface 500. The operation module 50A further comprises a location acquisition module 51A and an interaction module 52A. The location acquisition module 51A obtains the current location information through the intelligent terminal. The interaction module 52A controls the user interface 500 to interact with the user. Through the interaction module 52A to obtain the birth date inputted by the user via the user interface 500, the birth date is transmitted to the music analysis module 32A for classifying music. The location acquisition module 51A obtains the current location through the intelligent terminal and transmits it to the music analysis module 32A. The music analysis module 32A determines whether the current location is in the Southern Hemisphere based on the current location. If the current location is in the Southern Hemisphere, the music analysis module 32A needs to make the adaptive adjustments when classifying music according to the solar terms.

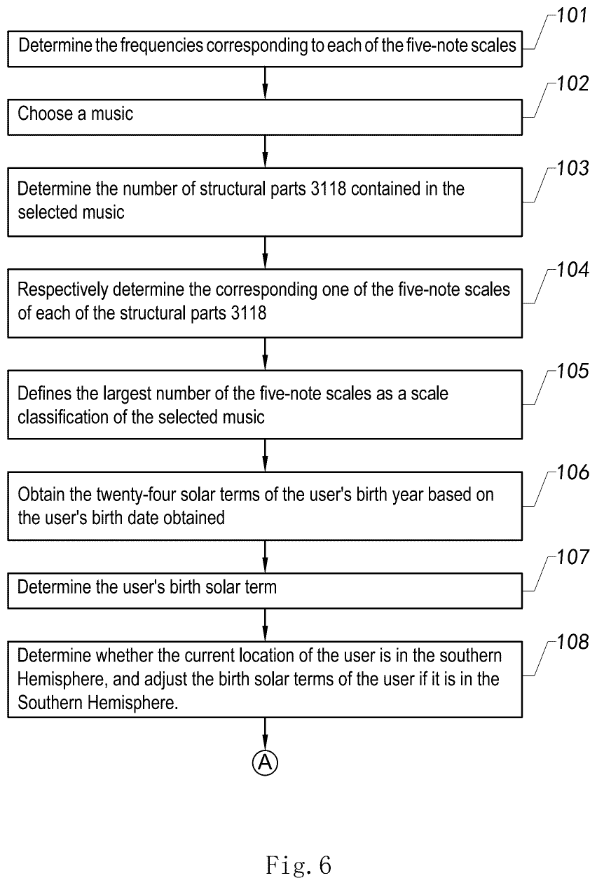

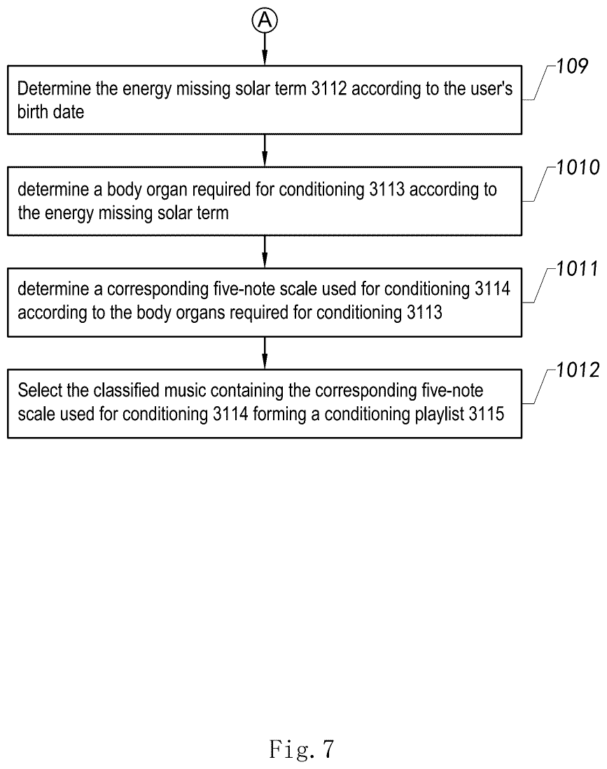

Referring to FIG. 5 to FIG. 6 of the drawing, a music recommendation method based on the location and the solar term according to a preferred embodiment of the present invention is illustrated, which comprising the steps as following:

101: Determine the frequencies corresponding to each of the five-note scales. The five-note scales are Gong, Shang, Jue, Zhi and Yu. For example, the Zhi scale corresponds to a frequency of 392.0 Hz. The Jue scale corresponds to a frequency of 329.6 Hz. The Gong scale corresponds to a frequency of 261.6. The Shang scale corresponds to a frequency of 293.7 Hz. The Yu scale corresponds to a frequency of 440.0 Hz.

102: Choose a piece of music. One piece of music can be selected from the storage module 20A.

103: Determine the number of structural parts 3118 contained in the selected music. For example, the selected music comprises five structural parts 3118. The way of dividing the structure part can be way according to the selected music's prelude, part A, part B, etc., in such a way that is dividing according to the music structure. Another way of dividing is to set the time length, according to the length of time to divide the structure part 3118.

104: Respectively determine the corresponding one of the five-note scales of each of the structural parts 3118. Specifically, the music analysis module 32A separately detects each of the structural parts 3118 of the selected music, to respectively confirm the contained the number of Gong scales, the number of Shang scales, the number of Jue scales, the number of Zhi scales, and the number of Yu scales among the five-note scale of each structural part 3118. For example, the selected music consists of five structural parts 3118. The first structural part 3118 contains three Gong scales and two Yu scales. Then the five-note scale corresponding to the first structural part is the Gong. In this way, the five-note scale corresponding to the second structural part is the Gong. The five-note scale corresponding to the third structural part is the Yu. The five-note scale corresponding to the fourth structural part is Zhi. The five-note scale corresponding to the fifth structural part is the Gong.

105: Defines the largest number of the five-note scales as a scale classification of the selected music. In the selected music, the five-note scale corresponding to the first, second and fifth structural part 3118 is the Gong, and the five-note scale corresponding to the fourth structural part 3118 is the Zhi. The five-note scale corresponding to the third structural part 3118 is the Yu. The largest number of the five-note scales is the Gong. The scale of the selected music is therefore classified as Gong. Preferably, the music classified by scale is stored in the storage module 32A.

106: Obtain the twenty-four solar terms of the user's birth year based on the user's birth date obtained. The birth date of the user as stated is Jun. 20, 1980. In 1980, Summer Solstice was on June 21, Grain in Ear was on June 5, and Minor Heat was on July 7, etc.

107: Determine the user's birth solar term. The birth date of the user is Jun. 20, 1980, which is closest to the date of the Summer Solstice of 1980 year on June 21. The user's birth solar term is the Summer Solstice.

108: Determine whether the current location of the user is in the southern Hemisphere, and adjust the birth solar terms of the user if it is in the Southern Hemisphere. The location of the user is in the northern Hemisphere, so there is no need to adjust the user's birth solar terms. If the user is located in the Southern Hemisphere, the birth solar term of the user is adjusted to the Winter Solstice. The twenty-four solar terms in the Northern Hemispheres and Southern Hemispheres are opposite seasons. For example, the Northern Hemisphere is Beginning of Spring, and the Southern Hemisphere is Beginning of Autumn. Rain Water in the Northern Hemisphere and End of Heat in the Southern Hemisphere. Spring Equinox in the Northern Hemisphere and Autumn Equinox in the Southern Hemisphere.

109: Determine the energy missing solar term 3112 according to the user's birth date. The user's birth solar term is the Summer Solstice. The energy missing solar term 3112 are Minor Heat, Major Heat, Beginning of Autumn, End of Heat, White Dew and Autumn Equinox. The users need to pay attention to the conditioning of heart, small intestine, spleen-stomach, lung and large intestine.

1010: determine a body organ required for conditioning 3113 according to the energy missing solar term. The energy missing solar term 3112 are Minor Heat, Major Heat, Beginning of Autumn, End of Heat, White Dew and Autumn Equinox. The body organs required for conditioning 3113 are the heart, spleen-stomach, and lung.

1011: determine a corresponding five-note scale used for conditioning 3114 according to the body organs required for conditioning 3113. The scales favorable for regulating the heart is Zhi music. The scales favorable for regulating the liver is Jue music. The scales favorable for regulating the spleen is Gong music. The scales favorable for regulating the lungs are Shang music. The scale beneficial for regulating the kidney is Yu music. The body organs required for conditioning 3113 of the user are heart, spleen-stomach, lung, then the corresponding five-note scale used for conditioning 3114 are the Zhi scale, the Gong scale and the Shang scale.

1012: Select the classified music containing the corresponding five-note scale used for conditioning 3114 forming a conditioning playlist 3115. The corresponding five-note scale used for conditioning the heart, the spleen-stomach, and the lung is the Zhi scale, the Gong scale and the Shang scale, the music after classified belonging to the Zhi scale, the Gong scale and the Shang scale is selected from the storage module 20A. Preferably, the selected music is formed into the conditioning playlist 3115. The conditioning playlist can be applied to the solar term user interface 300 and the constellation user interface 400.

The interaction module 32A can also control the user interface 300 to interact with the user. Input the birth date of the user through the user interface 300. The user interface 300 transmits the birth date of the user to the music module based on the solar term 30A through the intelligent terminal 60A.

The music module based on the solar term 30A receives the birth date of the user inputted with the user interface 300. The music module based on the solar term 30A obtains the user's birth solar term 3111 by analyzing the user's birth date. The music module based on the solar term 30A obtains the energy missing solar term 3112 according to the user's birth solar term. The music module based on the solar term 30A obtains the body organs required for conditioning 3113 according to the energy missing solar term. The music module based on the solar terms 30A obtains the scale used for conditioning the body organs of the user according to the body organs of the user required for conditioning. Adapted to be defined as the corresponding scale used for conditioning 3114 for user. The music module based on the solar term 30A obtains a corresponding conditioning frequency 3115 according to the scale used for conditioning by the user. The music module based on the solar term 30A then selects the corresponding instrument according to the corresponding conditioning frequency 3115. The music module based on the solar term 30A selects a plurality of conditioning music 3116 from the storage module 30A to form at least one conditioning playlist 3117 according to the corresponding scale used for conditioning 3114 by the user and its corresponding conditioning frequency 3115, and the selected instrument. The music module based on the solar term 30A is sent to the operation module 50A through the communication module 40A. The operation module 50A plays the conditioning playlist in the form of streaming media from the storage module 20A according to the conditioning playlist. The conditioning playlist 3117 is displayed on the intelligent terminal through the user interface 300.

The birth solar term determination module 31A determines the user's birth solar term 3111 based on the user's birth date. The solar term closest to the user's birth date is defined as the user's birth solar term 3111. The music analysis module 32A further obtains the energy missing solar term 3112 based on the user's birth solar term. The music analysis module 32A obtains the information of the body organs required for conditioning 3113 for the user through the energy missing solar term 3112. The music analysis module 32A further obtains the corresponding scale used for conditioning the user's body organs 3114 according to the information of the body organs required for conditioning. The music analysis module 32A obtains the conditioning frequency 3115 of sound according to the corresponding scale used for conditioning the user's body organs 3114. The music analysis module 32A selects the corresponding instrument according to the conditioning frequency of the corresponding sound. The recommendation module 33A selects a plurality of music from the storage module 20A to form the conditioning playlist according to the corresponding scale, the corresponding frequency and the selected instrument required for conditioning the user's body organs. The recommendation module 33A sends the conditioning playlist to the operation module 50A through the communication module 40A. The playback of the conditioning playlist is controlled by the operation module 50A. It is worth mentioning that the recommendation module 33A generates at least one piece of music containing the containing frequency according to the corresponding scale, the corresponding frequency and the selected instrument required for conditioning the user's body organs. The recommendation module 33A generates a conditioning playlist based on the generated music.

The music module based on the solar term 30A further comprises a playlist update module 34A. The playlist update module 34A is communicatively connected with the location acquisition device 10A. The playlist update module 34A can update the music in the playlist by default according to the venue change. The playlist update module 34A provides the option to update according to the change of venue, such as library, fitness room, study room, etc. The update module 36 provides the update options including updating by region, such as street, administrative district, city, etc., and also provides the user customization. Take the example of updating the playlist by venue for further illustration. The intelligent terminal 34A is playing music on a playlist. The location acquisition module 10A obtains the current location as a gym through the intelligent terminal 34A. Change the update options according to the preset venue. The playlist update module 34A transmits the information of entering the gym through the intelligent terminal 60A to the recommendation module 33A. The recommendation module 33A converts the gym information into the music suitable for playing during exercise. That is to say, the recommendation module 33A further selects the selected music conducive to the user's conditioning of scales, frequencies between the sounds and/or instruments from the music suitable for playing during exercise to form the exercise playlist. The playlist update module 36A updates the exercise playlist for playback while working out.

In a preferred embodiment of the present invention, the music analysis module 32A analyzes the tone of the music and performs the five-note classification of the music. Specifically, the music structure division module 321A analyzes the music and obtains the corresponding tone of the music. The music analysis module 32A further classifies the music into the five notes according to the corresponding tones of the music. For example, if the music analysis module 32A recognizes the tone of the music as the key C, the music analysis module 32A is classified to the Gong. The music analysis module 32A classifies the music of the key D as Shang. The music analysis module 32A classifies the music of the key E as Jue. The music analysis module 32A classifies the music of the key G as Zhi. The music analysis module 32A classifies the music of the key A as Yu. Specifically, the music structure division module 321A analyzes the tone of the music. The music structure division module 321A recognizes the tones of music as Key C, key D, key E, key G and key A, etc. It is worth mentioning that the music structure division module 321A identifies the tone of the music after identifying the tone of the music. Preferably, the music structure division module 321A adds the tone identifier of the music to the musical name of the music for easy identification. For example, the tone of the music is Key C, and the musical name of the music is “sky”. The music structure division module 321A adds the tone identifier “Key C” to the music name “sky” of the music, that is, the musical name of the music becomes “sky. Key C”. In this way, when the music structure division module 321A recognizes a piece of music, the music structure division module 321A first recognizes the musical name. If the musical name has the musical name, the music structure division module 321A identifies the tone identifiers contained in the musical name. It is worth mentioning that the classification module 323A classifies the music according to the tone identifier. The classification module 323A classifies the Key C as “Gong”, the key D as “Shang”, the key E as “Jue”, the key G as “Zhi”, and the key A as “Yu”. Preferably, the classification module 323A defines the alias for the music classification. Specifically, the alias of “Gong” as “earth”, the alias of “Shang” as “metal”, the alias of “Jue” as “wood”, the alias of “Zhi” as “fire”, the alias of “Yu” as “water”. In this way, the classification module 323A classifies the newly added music into one of the five notes classifications. In other words, if the new music is “sky.” The classification module 323A classifies the newly added music into the Gong. The newly added music “Sky. Tone” is displayed in the corresponding playlist.

It is worth mentioning that the user can query the corresponding music through the classification of the five-note scale. For example, when the user clicks on the label 502 of the user interface 500, the recommendation module 33A selects the music classified as the Gong in five notes and displays it in the corresponding playlist for playback.

One skilled in the art will understand that the embodiment of the present invention as shown in the drawings and described above is exemplary only and not intended to be limiting. It will thus be seen that the objects of the present invention have been fully and effectively accomplished. The embodiments have been shown and described for the purposes of illustrating the functional and structural principles of the present invention and are subject to change without departure from such principles. Therefore, this invention comprises all modifications encompassed within the spirit and scope of the following claims.

What is claimed is:

1. A music recommendation method based on a location and a solar term, performed by a computer, comprising one or more computers, comprising the steps as following:
A: Classify a selected music according to a five-note frequency, wherein step A further comprises the following steps:
A1: Determine a frequency respectively corresponding to a five-note scale, wherein said five-note scale is a Gong scale, a Shang scale, a Jue scale, a Zhi scale and a Yu scale;
A2: Select multiple pieces of music; and
A3: Respectively determine a scale classification corresponding to said selected pieces of music, wherein said scale classification of said music is defined as one of said five-note scales corresponding to said frequency of one of said five-note scales that said music contains the largest number of;
B: Determine a birth solar term of a user according to a birth date of the user obtained from a user interface; and
C: Select said music suitable for the user among said music in said scale classification according to said birth solar term of the user by forming a label which is the same as the name of said birth date of the user at a user interface to commend said selected music to the user.

2. The music recommendation method based on the location and the solar term performed by the computer, as recited in claim 1, wherein the step A3 further comprises the following steps:
A31: Determine a number of structural parts contained in said selected music;
A32: Determine said frequency corresponding to said five-note scale of one of the largest numbers contained in each structural part of said selected music;
A33: Determine said scale classification of said structure part which is one of said corresponding five-note scale corresponding to said frequency corresponding to one of the largest number of said five-note scales according to said frequency corresponding to one of the largest number of said five-note scales; and
A34: Define the largest number of said scale classification of said selected structure parts as said scale classification of said selected music.

3. The music recommendation method based on the location and the solar term performed by the computer, as recited in claim 1, wherein the step B further comprises the following steps:
B1: Determine the corresponding dates of said twenty-four solar terms of a birth year of the user according to said birth date of the user; and
B2: Determine said birth solar term of the user, wherein said solar term of the date closest to said birth date of the user is taken as said birth solar term of the user.

4. The music recommendation method based on the location and the solar term performed by the computer, as recited in claim 3, wherein the step B further comprises the following steps:
B3: Determine whether it is in the Southern Hemisphere according to said current obtained location. If said current location is in the Southern Hemisphere, adjust said birth solar term of the user to match said solar term in the Southern Hemisphere.

5. The music recommendation method based on the location and the solar term performed by the computer, as recited in claim 3, wherein the step C further comprises the following steps:
C1: Determine an energy missing solar term according to said user's birth solar term;
C2: Determine a body organ required for conditioning according to said energy missing solar term;
C3: Determine said five-note scale used for conditioning said body organ according to said body organ required for conditioning;
C4: Select said music respectively corresponding to said five-note scale used for conditioning said body organ from said classified music, and form a conditioning playlist for playback.

6. A music playing system based on a location and a solar term, comprising:
one or more processors; and
one or more storage devices, communicatively connected to said one or more processors, wherein said storage device comprises a computer readable instruction, said computer readable instruction is stored in said storage device, when said computer readable instruction is executed by said processor, causing said processor to perform the following operations, so as to:
classify a plurality of pieces of selected music according to corresponding frequencies of a five-note scale to create a five-note scale music classification, wherein said five-note scale is a Gong scale, a Shang scale, a Jue scale, a Zhi scale and a Yu scale;
determine a birth solar term of the user based on a user's obtained birth date; and
select a music suitable for the user among said five-note scale music classification according to said birth solar term of the user by forming a label which is the same as the name of said birth date of the user at a user interface to commend said selected music to the user for playback.

7. The music playing system based on the location and the solar term, as recited in claim 6, wherein said storage device further comprises the instruction, so as to:
Respectively determine said frequencies corresponding to said Gong scale, said Shang scale, said Jue scale, said Zhi scale and said Yu scale;
select multiple pieces of music;
determine said belonging scale classification of each of multiple pieces of music, wherein said scale classification is selected from one of said Gong scale, said Shang scale, said Jue scale, said Zhi scale and said Yu scale, wherein said five-note scale corresponding to the largest number of frequencies of one of said five-note scales contained in said music is regarded as said scale classification of said music.

8. The music playing system based on the location and the solar term, as recited in claim 7, wherein said storage device further comprises the instructions, so as to:
determine the number of structural parts comprised in said selected music;
determine said frequency corresponding to said five-note scale of one of the largest numbers contained in each structural part of said selected music;
determine said scale classification of said structure part which is one of said corresponding five-note scale corresponding to said frequency corresponding to one of the largest number of said five-note scales according to said frequency corresponding to one of the largest number of said five-note scales;
define the largest number of said scale classification of said selected structure parts as said scale classification of said selected music.

9. The music playing system based on the location and the solar term, as recited in claim 8, wherein said storage device further comprises the instructions, so as to
determine the corresponding dates of said twenty-four solar terms of a birth year of the user according to said birth date of the user; and
determine said birth solar term of the user, wherein said solar term of the date closest to said birth date of the user is taken as said birth solar term of the user.

10. The music playing system based on the location and the solar term, as recited in claim 9, wherein said storage device further comprises the instructions, so as to:
determine whether it is in the Southern Hemisphere according to said current obtained location. If said current location is in the Southern Hemisphere, adjust said birth solar term of the user to match said solar term in the Southern Hemisphere.

11. The music playing system based on the location and the solar term, as recited in claim 10, wherein said storage device further comprises the instructions, so as to:
determine an energy missing solar term according to said user's birth solar term;
determine a body organ required for conditioning according to said energy missing solar term;
determine said five-note scale used for conditioning said body organ according to said body organ required for conditioning; and
select said music respectively corresponding to said five-note scale used for conditioning said body organ from said classified music, and form a conditioning playlist for playback.

12. A music player based on a location and a solar term, comprising:
a processor;
a location acquisition device, used to obtain a current location;
a storage device;
a communication device;
a power supply device; and
a housing, wherein said processor, said location acquisition device, said storage device, said communication device and said power supply device are placed in said housing, wherein said processor is respectively communicatively connected to said location acquisition device, said communication device, said storage device and said power supply device, wherein said power supply device supplies an electrical energy to said processor, said location acquisition device, said communication device and said storage device, wherein said processor is obtained a birth date and is obtained a conditioning frequency used by a user for conditioning, wherein said processor is selected said music with said conditioning frequency according to a containing frequency for playing.

13. The music player based on the location and the solar term, as recited in claim 12, wherein said music player based on said location and said solar term further comprises a touch screen arranged in said housing, wherein said processor is communicatively connected to said touch screen, wherein said processor is received said birth date input by said touch screen.

14. The music player based on the location and the solar term, as recited in claim 13, wherein said processor further comprises a birth term determining device and a music selecting device, and said birth term determining device is communicatively connected with said music selecting device, wherein said birth term determining device determines a birth solar term according to said received birth date; said music selecting device obtains a conditioning frequency for conditioning according to said birth solar term, wherein said music selecting device selects a music with said conditioning frequency for playback according to said conditioning frequency for conditioning.

15. The music player based on the location and the solar term, as recited in claim 14, wherein said birth term determining device obtains a current location from said location acquisition device, wherein if said current location is in a Southern Hemisphere, said birth term determining device makes corresponding adjustments to said birth solar term in the Southern Hemisphere.

16. The music player based on the location and the solar term, as recited in claim 15, wherein said music selecting device further comprises a solar term scale acquiring device, a solar term frequency acquiring device and a selector, said selector is communicatively connected with said solar term scale acquiring device and said solar term frequency acquiring device, wherein said solar term scale acquiring device obtains an energy missing solar term according to said birth solar term, said solar term scale acquiring device obtains a body organ required for conditioning according to said energy missing solar term, and said solar term scale acquiring device obtains at least one conditioning scale according to said body organ that needs to be regulated; said solar term frequency acquiring device obtains at least one corresponding conditioning frequency according to at least one conditioning scale, wherein said selector selects said music with at least one conditioning frequency according to at least one conditioning frequency for playback.

17. The music player based on the location and the solar term, as recited in claim 16, wherein said solar term frequency acquiring device provides at least one musical instrument capable of producing at least one conditioning frequency for choice according to at least one conditioning frequency, said selector selects said music with at least one conditioning frequency for playback based on at least one conditioning frequency and the instrument that can produce at least one conditioning frequency.

18. The music player based on the location and the solar term, as recited in claim 16, wherein said music selecting device further comprises a music parser, said music parser is for analyzing a structural part of said music and whether each structural part of said music has a conditioning frequency, wherein said music parser analyzes at least one music with said conditioning frequency selected by said selector, and said music parser sorts at least one music with said conditioning frequency selected by said selector from most to least according to the number of structural parts with said conditioning frequency; from said music with said conditioning frequency, 24 pieces of music with said structural parts of said conditioning frequency are selected to form a conditioning playlist for playing.

19. The music player based on the location and the solar term, as recited in claim 18, wherein said music selecting device further comprises a generator, wherein said generator generates the instrument corresponding to at least one containing frequency according to at least one containing frequency, and generates at least one music with said conditioning frequency for playback.

20. The music player based on the location and the solar term, as recited in claim 19, wherein said music parser identifies said tone of said music, and said generator classifies said music according to said tone recognized by said music parser, wherein said music parser facilitates said generator to classify said music according to said musical name by adding a corresponding tone to said music name, wherein a Key C corresponds to a Gong scale, a key D corresponds to a Shang scale, a key E corresponds to a Jue scale, a key G corresponds to a Zhi scale and a key A corresponds to a Yu scale.
